(19) United States
(12) Patent Application Publication
(10) Pub. No.: US 2026/0136810 A1
(43) Pub. Date: May 14, 2026

(54) MOTHER BOARD FOR DISPLAY DEVICE

(71) Applicant: Magnolia White Corporation, Tokyo (JP)

(72) Inventors: Naoya IWAHASHI, Tokyo (JP); Sho YANAGISAWA, Tokyo (JP); Tomokazu ISHIKAWA, Tokyo (JP)

(73) Assignee: Magnolia White Corporation, Tokyo (JP)

(21) Appl. No.: 19/386,270

(22) Filed: Nov. 12, 2025

(30) Foreign Application Priority Data
Nov. 12, 2024 (JP) 2024-197539
Jul. 9, 2025 (JP) 2025-115665

(51) Int. Cl. H10K 59/80; H10K 59/122

(52) U.S. Cl. CPC H10K 59/873; H10K 59/122

(57) ABSTRACT

According to one embodiment, a mother board for a display device includes a display area for displaying images, a margin area on an outer side of a cut line for cutting out the display area, a display element disposed in the display area, a first partition disposed in the margin area and including a plurality of first segments and a plurality of second segments, and a first sealing layer formed of an inorganic insulating material, and disposed above the display elements and the first segments but not above the second segments. The second segments have a planar shape different from that of the first segments.

### CROSS-REFERENCE TO RELATED APPLICATIONS

This application is based upon and claims the benefit of priority from Japanese Patent Applications No. 2024-197539, filed Nov. 12, 2024, and No. 2025-115665, filed Jul. 9, 2025, the entire contents of each are incorporated herein by reference.

### FIELD

Embodiments described herein relate generally to a mother board for a display device.

### BACKGROUND

In recent years, display devices in which organic light-emitting diodes (OLEDs) are applied as display elements have been put into practical use. In display devices of this type, a technology of improving yield is required.

### BRIEF DESCRIPTION OF THE DRAWINGS

FIG. 1 is a diagram showing a configuration example of a display device according to the first embodiment.

FIG. 2 is a plan view schematically showing an example of layout of subpixels.

FIG. 3 is a cross-sectional view schematically showing a display panel taken along the line III-III in FIG. 2.

FIG. 4 is a plan view schematically showing a mother board according to the first embodiment.

FIG. 5 is a plan view schematically showing a part of the mother board.

FIG. 6 is a plan view schematically showing an island-like portion and its vicinity.

FIG. 7 is an enlarged view schematically showing a portion VII in FIG. 6.

FIG. 8 is a schematic cross-sectional view taken along the line VIII-VIII in FIG. 7.

FIG. 9 is a flowchart showing an example of a method of manufacturing the display device.

FIG. 10A is a schematic cross-sectional view showing a processing step in the manufacturing of the display device.

FIG. 10B is a schematic cross-sectional view showing a processing step following that of FIG. 10A.

FIG. 10C is a schematic cross-sectional view showing a processing step following that of FIG. 10B.

FIG. 10D is a schematic cross-sectional view showing a processing step following that of FIG. 10C.

FIG. 10E is a schematic cross-sectional view showing a processing step following that of FIG. 10D.

FIG. 10F is a schematic cross-sectional view showing a processing step following that of FIG. 10E.

FIG. 10G is a schematic cross-sectional view showing a processing step following that of FIG. 10F.

FIG. 10H is a schematic cross-sectional view showing a processing step following that of FIG. 10G.

FIG. 10I is a schematic cross-sectional view showing a processing step following that of FIG. 10H.

FIG. 10J is a schematic cross-sectional view showing the processing step following that of FIG. 10I.

FIG. 11A is a schematic cross-sectional view showing a configuration of a margin area during a processing step in the manufacturing of the display device.

FIG. 11B is a schematic cross-sectional view showing a processing step following that of FIG. 11A.

FIG. 11C is a schematic cross-sectional view showing a processing step following that of FIG. 11B.

FIG. 11D is a schematic cross-sectional view showing the processing step following that of FIG. 11C.

FIG. 12 is a schematic enlarged view showing a display device according to the second embodiment.

FIG. 13 is a schematic cross-sectional view taken along the line XIII-XIII in FIG. 12.

FIG. 14 is a schematic enlarged view showing a display device according to the third embodiment.

FIG. 15 is a schematic cross-sectional view taken along the line XV-XV in FIG. 14.

### DETAILED DESCRIPTION

In general, according to one embodiment, a mother board for a display device, comprises a display area for displaying images, a margin area on an outer side of a cut line for cutting out the display area, a display element disposed in the display area, a first partition disposed in the margin area and including a plurality of first segments and a plurality of second segments, and a first sealing layer formed of an inorganic insulating material, disposed above the display elements and the first segments, and not disposed above the plurality of second segments. The plurality of second segments have a planar shape different from that of the plurality of first segments.

According to another embodiment, a mother board for a display device comprises a display area for displaying images, a margin area on an outer side of a cut line for cutting out the display area, an inorganic insulating layer disposed in the display area and the margin area, a display element disposed in the display area, a first partition disposed above the inorganic insulating layer in the margin area, and including a plurality of first segments and a plurality of second segments, and a first sealing layer formed of an inorganic insulating material and disposed above the display element and the plurality of first segments but not above the second segments, and a resin layer disposed above the first sealing layer in the margin area.

With configurations such as described above, it is possible to provide a mother board for display device which can improve the yield.

Embodiments will now be described hereinafter with reference to the accompanying drawings. Note that the disclosure is merely an example, and proper changes within the spirit of the invention, which are easily conceivable by a skilled person, are included in the scope of the invention as a matter of course. In addition, as to the drawings, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary. Further, note that, in order to make the descriptions more easily understandable, some of the drawings illustrate an X axis, a Y axis and a Z axis orthogonal to each other. A direction along the X axis is referred to as a first direction X, a direction along the Y axis is referred to as a second direction Y and a direction along the Z axis is referred to as a third direction Z. Moreover, viewing the constitutional elements parallel to the Z direction is referred to as plan view.

The display device according to each of the embodiments is an organic electroluminescence display device comprising organic light-emitting diodes (OLEDs) as display elements, and may be incorporated into various electronic devices such as televisions, personal computers, in-vehicle devices, tablet terminals, smartphones, mobile phone terminals, wearable devices and the like.

### First Embodiment

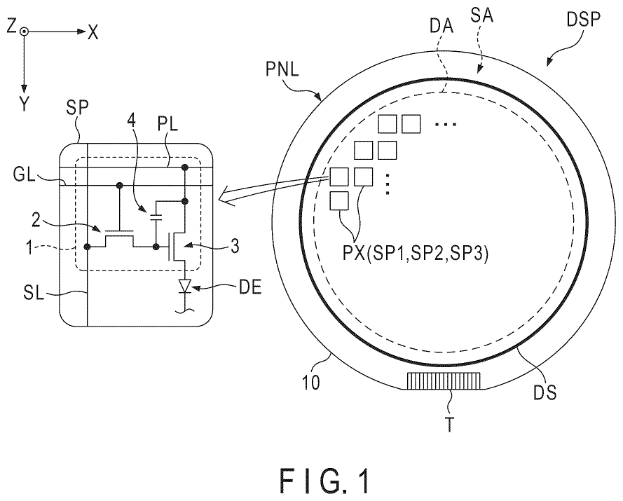

FIG. 1 is a diagram showing a configuration example of a display device DSP according to this embodiment. The display device DSP includes a display panel PNL comprising an insulating substrate 10. The display panel PNL has a display area DA which displays images and a peripheral area SA surrounding the display area DA. The substrate 10 may be glass or a flexible resin film.

In this embodiment, the shape of the substrate 10 and the display area DA, in plan view, is circular. Here, the circular shape is not limited to a perfect circle and includes shapes such as a partially cut-out circle, an elliptical shape, and an oblong shape. Further, the shape of the substrate 10 and the display area DA, in plan view, is not limited to a circle and may also be some other shape such as a rectangle, a square, or an ellipse.

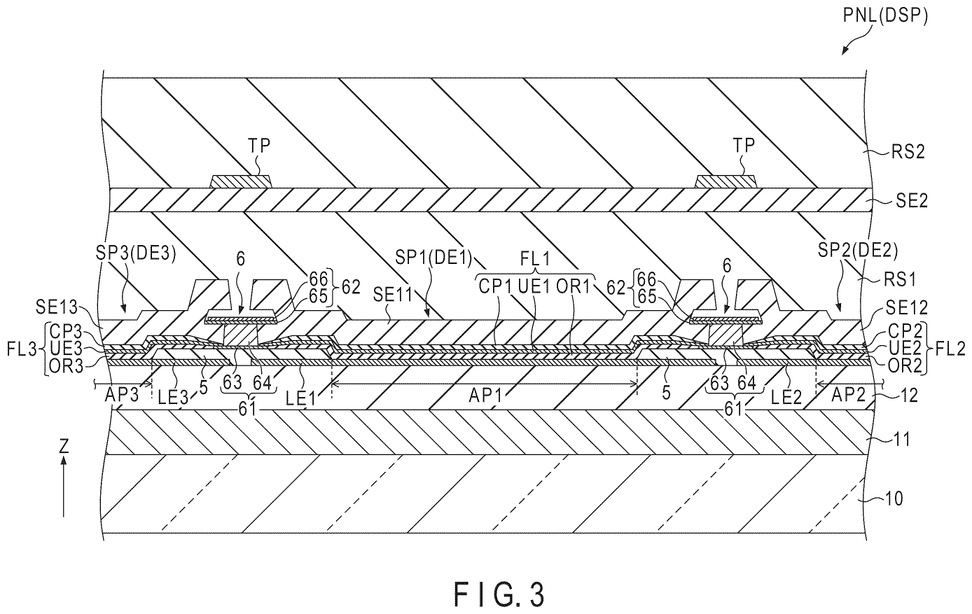

In the example of FIG. 1, a ring-shaped dam structure DS is disposed in the peripheral area SA. The dam structure DS surrounds the display area DA. The shape of the dam structure DS in plan view is, for example, circular, but is not limited to that of this example. The dam structure DS can be formed, for example, from an organic insulating layer 12, which will be described later (see FIG. 3).

The display area DA comprises a plurality of pixels PX arranged in a matrix along the first direction X and the second direction Y. Each of the pixels PX contains a plurality of subpixels SP that display different colors. In this embodiment, it is assumed that each pixel PX includes a subpixel SP1 of a first color, a subpixel SP2 of a second color, and a subpixel SP3 of a third color. For example, the first color is blue, the second color is green, and the third color is red, but the colors assigned are not limited to these of this example. The pixel PX may contain another subpixel SP of some other color such as white, an addition to or in place of any of the subpixels SP1, SP2, and SP3.

The display device DSP further includes a terminal portion T disposed in the peripheral area SA. To the terminal portion T, a flexible circuit board which, for example, supplies voltage and signals for driving the display device DSP, is connected.

Each of the subpixels SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are switching elements constituted, for example, by thin-film transistors.

In the display area DA, a plurality of scanning lines GL that supply scanning signals to the pixel circuits 1 of the respective subpixels SP, a plurality of signal lines SL that supply image signals to the pixel circuits 1 of the respective subpixels SP, and a plurality of power lines PL. In the example of FIG. 1, the scanning lines GL and power lines PL extend along the first direction X, and the signal lines SL extend along the second direction Y.

The gate electrode of the pixel switch 2 is connected to the respective scanning line GL. One of the source electrode and drain electrode of the pixel switch 2 is connected to the respective signal line SL, and the other is connected to the gate electrode of the drive transistor 3 and the capacitor 4. In the drive transistor 3, one of the source electrode and drain electrode is connected to the power line PL and the capacitor 4, and the other is connected to the display element DE.

Note that the configuration of the pixel circuit 1 is not limited to that of the example illustrated above. For example, the pixel circuit 1 may include more thin-film transistors and capacitors.

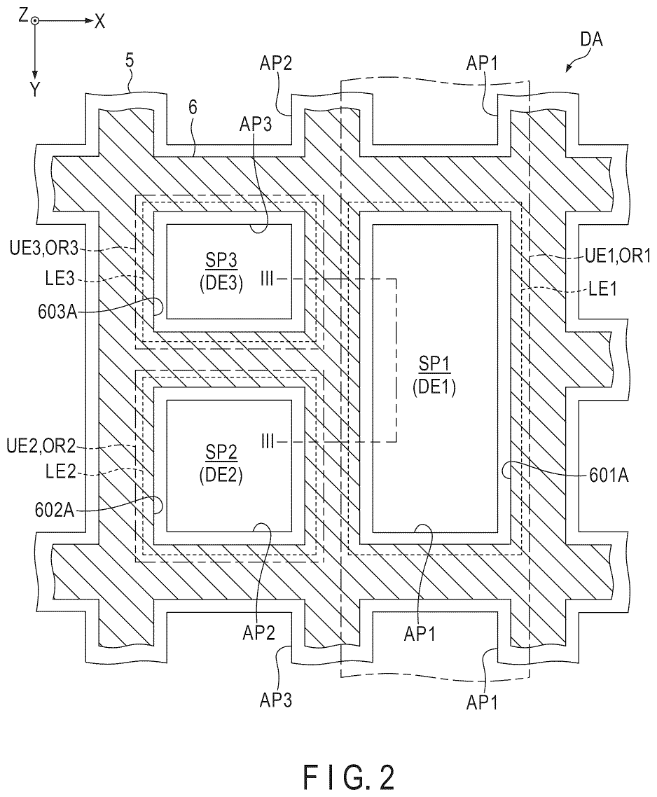

FIG. 2 is a plan view schematically showing an example of the layout of the subpixels SP1, SP2, and SP3. In the example shown in FIG. 2, the subpixels SP2 and SP3 are disposed along the subpixel SP1 in the first direction X. Further, the subpixels SP2 and SP3 are disposed along the second direction Y.

When the subpixels SP1, SP2, and SP3 are disposed in such a layout, a column in which the subpixels SP2 and SP3 are alternately disposed along the second direction Y, and a column in which a plurality of subpixels SP1 are repeatedly disposed along the second direction Y are formed in the display area DA. These columns are disposed alternately along the first direction X. Note that the layout of the subpixels SP1, SP2, and SP3 is not limited to that of the example shown in FIG. 2.

In the display area DA, a rib layer 5 is disposed. In this embodiment, the rib layer 5 is an example of the inorganic insulating layers. The rib layer 5 has pixel apertures AP1, AP2, and AP3 in the subpixels SP1, SP2, and SP3, respectively. In the example shown in FIG. 2, the pixel aperture AP1 is larger than the pixel aperture AP2, and the pixel aperture AP2 is larger than the pixel aperture AP3. That is, among the subpixels SP1, SP2, and SP3, the aperture ratio of the subpixel SP1 is the largest, and the aperture ratio of the subpixel SP3 is the smallest. Note that the sizes of the pixel apertures AP1, AP2, and AP3 are not limited to those of this example.

The subpixel SP1 comprises a lower electrode LE1, an upper electrode UE1, and an organic layer OR1, each overlapping the pixel aperture AP1. The subpixel SP2 comprises a lower electrode LE2, an upper electrode UE2, and an organic layer OR2, each overlapping the pixel aperture AP2. The subpixel SP3 includes a lower electrode LE3, an upper electrode UE3, and an organic layer OR3, each overlapping the pixel aperture AP3.

The portions of the lower electrode LE1, upper electrode UE1, and organic layer OR1, which overlap the pixel aperture AP1 constitute a display element DE1 of the subpixel SP1. The portions of the lower electrode LE2, upper electrode UE2, and organic layer OR2, which overlap the pixel aperture AP2 constitute a display element DE2 of the subpixel SP2. The portions of the lower electrode LE3, upper electrode UE3, and organic layer OR3, which overlap the pixel aperture AP3 constitute a display element DE3 of the subpixel SP3. The display elements DE1, DE2, and DE3 may further include a cap layer, which will be described later. The rib layer 5 surrounds each of the display elements DE1, DE2, and DE3.

Above the rib layer 5, a conductive partition 6 (second partition) is disposed. The partition 6 functions as wiring lines supplying a common voltage to the upper electrodes UE1, UE2, and UE3. The partition 6 overlaps the rib layer 5 entirely and has a planar shape similar to that of the rib layer 5.

Specifically, the partition 6 has a partition aperture 601A in the subpixel SP1, a partition aperture 602A in the subpixel SP2, and a partition aperture 603A in the subpixel SP3. The partition apertures 601A, 602A, and 603A entirely overlap the pixel apertures AP1, AP2, and AP3, respectively. Further, the partition apertures 601A, 602A, and 603A entirely overlap the display elements DE1, DE2, and DE3, respectively. That is, the partition 6 surrounds the display elements DE1, DE2, and DE3.

FIG. 3 is a schematic cross-sectional view of the display panel PNL taken along the line III-III in FIG. 2. On the substrate 10 described above, a circuit layer 11 is disposed. The circuit layer 11 includes various circuits and wiring lines such as the pixel circuit 1, scanning lines GL, signal lines SL, and power lines PL shown in FIG. 1. The circuit layer 11 is covered by an organic insulating layer 12. The organic insulating layer 12 functions as a planarization film that planarizes the unevenness caused by the circuit layer 11.

Lower electrodes LE1, LE2, and LE3 are placed on the organic insulating layer 12. The rib layer 5 is placed on the organic insulating layer 12 and the lower electrodes LE1, LE2, and LE3. The end portions of the lower electrodes LE1, LE2, and LE3 are covered by the rib layer 5. Although not shown in the cross-section of FIG. 3, the lower electrodes LE1, LE2, and LE3 are connected to the pixel circuit 1 of the circuit layer 11 through respective contact holes provided in the organic insulating layer 12.

The partition 6 includes a conductive lower portion 61 disposed on the rib layer 5 and an upper portion 62 disposed on the lower portion 61. In this embodiment, the lower portion 61 of the partition 6 corresponds to the second lower portion, and the upper portion 62 of the partition 6 corresponds to the second upper portion.

The upper portion 62 has a width greater than that of the lower portion 61. With this configuration, both end portions of the upper portion 62 protrude beyond the respective side surfaces of the lower portion 61. Such a shape of the partition 6 is referred to as an overhanging shape.

In the example of FIG. 3, the lower portion 61 includes a bottom layer 63 disposed on the rib layer 5 and an axial layer 64 disposed on the bottom layer 63. For example, the bottom layer 63 is formed thinner than the axial layer 64. Further, in the example of FIG. 3, both end portions of the bottom layer 63 protrude beyond the respective side surfaces of the axial layer 64.

Furthermore, in the example of FIG. 3, the upper portion 62 includes a first top layer 65 and a second top layer 66 disposed on the first top layer 65. For example, the width of the second top layer 66 is slightly less than the width of the first top layer 65. Note here that the configuration is not limited to this, and the first top layer 65 and the second top layer 66 may have equivalent widths.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the side surfaces of the lower portion 61 of the partition 6.

The display element DE1 includes a cap layer CP1 disposed on the upper electrode UE1. The display element DE2 includes a cap layer CP2 disposed on the upper electrode UE2. The display element DE3 includes a cap layer CP3 disposed on the upper electrode UE3. The cap layers CP1, CP2, and CP3 function as optical adjustment layers that improve the light extraction efficiency of the organic layers OR1, OR2, and OR3, respectively.

In the following descriptions, the stacked multilayer body comprising the organic layer OR1, upper electrode UE1, and cap layer CP1 is referred to as a stacked multilayer film FL1, the stacked multilayer body comprising the organic layer OR2, upper electrode UE2, and cap layer CP2 is referred to as a stacked multilayer film FL2, and the stacked multilayer body comprising the organic layer OR3, upper electrode UE3, and cap layer CP3 is referred to as a stacked multilayer film FL3.

On the subpixels SP1, SP2, and SP3, sealing layers SE11, SE12, and SE13 are respectively disposed. The sealing layer SE11 continuously covers the stacked multilayer film FL1 and the partition 6 surrounding the subpixel SP1. The sealing layer SE12 continuously covers the stacked multilayer film FL2 and the partition 6 surrounding the subpixel SP2. The sealing layer SE13 continuously covers the stacked multilayer film FL3 and the partition 6 surrounding the subpixel SP3.

In the example of FIG. 3, the sealing layer SE11 on the partition 6 between the subpixels SP1 and SP2 is spaced apart from the sealing layer SE12 on the same partition 6. Further, the sealing layer SE11 on the partition 6 between the subpixels SP1 and SP3 is spaced apart from the sealing layer SE13 on the same partition 6. Note here that any two of the sealing layers SE11, SE12, and SE13 may be brought into contact with each other, above the partition 6.

For example, between the sealing layers SE11, SE12, SE13 and the upper portion 62 of the partition 6, gaps are formed, respectively. The stacked multilayer films FL1, FL2, FL3 may be disposed in at least some of these gaps.

The sealing layers SE11, SE12, and SE13 are covered by the resin layer RS1. The resin layer RS1 is covered by the sealing layer SE2. The sealing layer SE2 is covered by the resin layer RS2. The resin layers RS1, RS2, and the sealing layer SE2 are continuously provided over at least the entire display area DA, and a portion thereof even extends to the peripheral area SA as well.

In the example of FIG. 3, touch panel electrodes TP are disposed on top of the sealing layer SE2. The touch panel electrodes TP are covered by the resin layer RS2. The touch panel electrodes TP can be formed from metal wiring lines. These wiring lines may face the partition 6 along the third direction Z. Further, the wiring lines may have a planar shape similar to that of the partition 6.

A cover member, such as a polarizer, protective film, or cover glass, may be further disposed above the resin layer RS2. Such a cover member may be adhered to the resin layer RS2 via an adhesive layer such as optical clear adhesive (OCA).

The organic insulating layer 12 is formed from an organic insulating material such as polyimide. The rib layer 5 and the sealing layers SE11, SE12, SE13, SE2 are formed from inorganic insulating materials such as silicon nitride (SiNx), silicon oxide (SiOx), and silicon oxynitride (SiON). In one example, the rib layer 5 is formed of silicon oxynitride, and the sealing layers SE11, SE12, SE13, and SE2 are formed of silicon nitride. The resin layers RS1, and RS2 are formed of resin materials (organic insulating materials) such as epoxy resin and acrylic resin.

The lower electrodes LE1, LE2, LE3 each comprise a reflective layer formed of, for example, silver, and a pair of conductive oxide layers covering the upper and lower surfaces of this reflective layer, respectively. Each of the conductive oxide layers can be formed from, for example, a conductive transparent oxide such as indium tin oxide (ITO), indium zinc oxide (IZO), or indium gallium zinc oxide (IGZO).

The upper electrodes UE1, UE2, and UE3 are formed from a metal material such as a magnesium-silver alloy (MgAg). For example, the lower electrodes LE1, LE2, and LE3 correspond to the anodes, and the upper electrodes UE1, UE2, and UE3 correspond to the cathodes.

The organic layers OR1, OR2, and OR3 are constituted by a plurality of thin films including a light-emitting layer. For example, the organic layers OR1, OR2, and OR3 have a structure in which a hole injection layer, a hole transport layer, an electron blocking layer, an emissive layer, a hole blocking layer, an electron transport layer, and an electron injection layer are sequentially stacked along the third direction Z. Note here that the organic layers OR1, OR2, and OR3 may as well have some other structure, such as the so-called tandem structure including a plurality of light-emitting layers.

The cap layers CP1, CP2, and CP3 have, for example, a stacked layer structure in which a plurality of transparent layers are stacked one on another. These transparent layers may include a layer formed from an inorganic material and a layer formed from an organic material. Further, these transparent layers have different refractive indices. For example, the refractive indices of these transparent layers are different from the refractive indices of the upper electrodes UE1, UE2, UE3 and those of the sealing layers SE11, SE12, SE13. Note that at least one of the cap layers CP1, CP2, CP3 may be omitted.

The bottom layer 63 and axial layer 64 of the partition 6 are formed from respective metal materials. As the metal material for the bottom layer 63, for example, molybdenum, titanium, titanium nitride (TiN), molybdenum-tungsten alloy (MoW), or molybdenum-niobium alloy (MoNb) can be used. As the metal material for the axial layer 64, for example, aluminum, aluminum-neodymium alloy (AlNd), aluminum-yttrium alloy (AlY), or aluminum-silicon alloy (AlSi) can be used. Note that the axial layer 64 may as well be formed from an insulating material.

The first top layer 65 of the partition 6 is formed, for example, from a metal material. Meanwhile, the second top layer 66 of the partition 6 is formed, for example, from a conductive oxide. As the metal material for forming the first top layer 65, for example, titanium, titanium nitride, molybdenum, tungsten, molybdenum-tungsten alloy, or molybdenum-niobium alloy can be used. Examples of the conductive oxides used for forming the second top layer 66 include ITO or IZO. Note that the upper portion 62 may be constituted by three or more layers or may be formed from a single layer. Further, the upper portion 62 may include a layer formed from an insulating material.

A common voltage is supplied to the partition 6. The common voltage is supplied to each of the upper electrodes UE1, UE2, and UE3, which are in contact with the side surfaces of the lower portion 61. To the lower electrodes LE1, LE2, and LE3, pixel voltage corresponding to the image signal on the signal lines SL are supplied through the pixel circuits 1 of the subpixels SP1, SP2, and SP3, respectively.

The organic layers OR1, OR2, and OR3 emit light according to the voltage applied. Specifically, when a potential difference is formed between the lower electrode LE1 and the upper electrode UE1, the light-emitting layer of the organic layer OR1 emits light in the wavelength range of the first color. When a potential difference is formed between the lower electrode LE2 and the upper electrode UE2, the light-emitting layer of the organic layer OR2 emits light in the wavelength range of the second color. When a potential difference is formed between the lower electrode LE3 and the upper electrode UE3, the light-emitting layer of the organic layer OR3 emits light in the wavelength range of the third color.

During the manufacturing of the display device DSP, a large-scale mother board including a plurality of areas corresponding to respective display panels PNL is fabricated. The configuration applicable to this mother board will now be described.

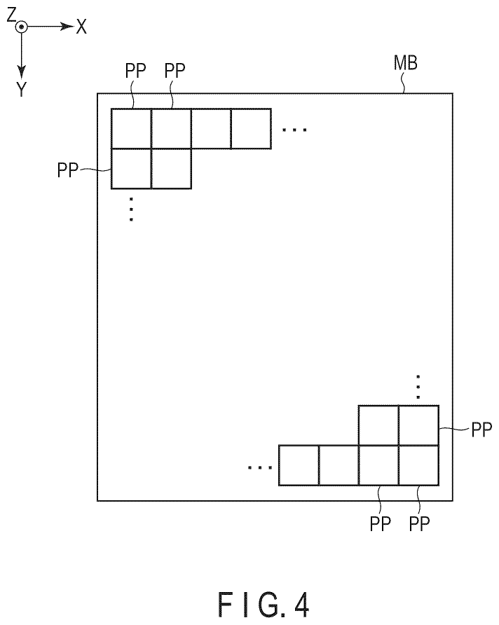

FIG. 4 is a schematic plan view of a mother board MB (mother board for display device) according to this embodiment. The mother board MB is, for example, rectangular as shown, but may as well be circular or some other shape.

The mother board MB has a plurality of panel portions PP arranged in a matrix pattern. In the example of FIG. 4, the panel portions PP are arranged continuously along the first direction X and the second direction Y. Note that the arrangement pattern of the panel portions PP on the mother board MB is not limited to that of this example.

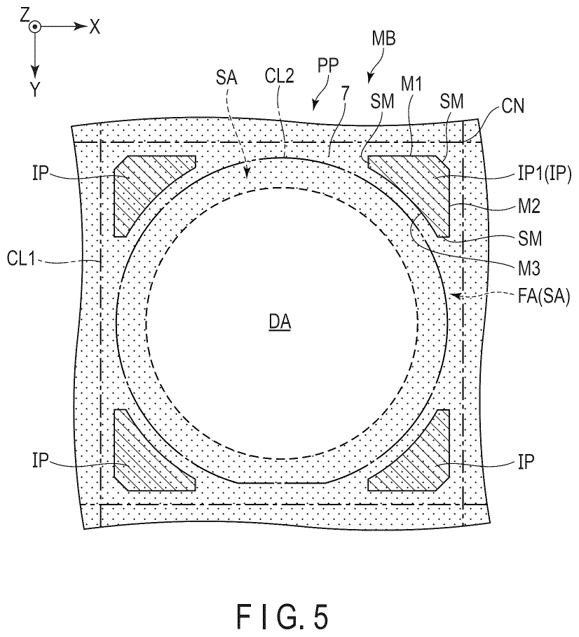

FIG. 5 is a schematic plan view of a part of the mother board MB. FIG. 5 focuses on one of the panel portions PP shown in FIG. 4.

The shape of the panel portion PP in plan view is square in the example of FIG. 5. Note that the shape of the panel portion PP in plan view may as well be a rectangular shape elongated along the first direction X or elongated along the second direction Y. Further, the shape of the panel portion PP in plan view may include a plurality of straight portions and curved portions.

The outer shape of each panel portion PP corresponds to a cut line CL1 for cutting out each panel portion PP from the mother board MB. The cut line CL1 is formed into a grid pattern. Focusing on a single panel portion PP, the cut line CL1 is formed into a quadrangular shape.

Further, a cut line CL2 is formed on the panel portions PP. The cut line CL2 corresponds to the outer shape of the display panel PNL shown in FIG. 1. In other words, the cut line CL2 is formed into a circular shape. The cut line CL2 corresponds to the cut line for cutting out the display area DA and a part of the peripheral area SA from the panel portion PP.

The panel portion PP has the display area DA and peripheral area SA described above. The peripheral area SA includes the margin area FA on an outer side of the cut line CL2. The margin area FA corresponds, for example, to the area between the cut line CL1 and the cut line CL2. The cut line CL1 corresponds to the cut line for cutting out the display area DA and the margin area FA from the mother board MB.

The panel portion PP is divided by the cut line CL2 into a portion including the display area DA and a portion including the margin area FA. Between the cut line CL1 and cut line CL2, a plurality of inspection pads (not shown) for inspecting the operation of the display panel PNL are disposed.

In this embodiment, the partition 7 (first partition) is disposed in the peripheral area SA including the margin area FA. In FIG. 5, the regions where the partition 7 can be placed are indicated by a dotted pattern. The partition 7 can be placed in the regions between the display area DA and the cut line CL2, in the margin area FA and the like. Note that the partition 7 need not be placed in at least one of these regions. Furthermore, the placement position and planar shape of the partition 7 in these areas may be determined as appropriate.

From the perspective of efficiently cutting out the panel portions PP, it is preferable that the partition 7 should not be provided on the cut line CL1. Similarly, it is preferable that the partition 7 should not be provided on the cut line CL2.

The margin area FA has a plurality of island-like portions IP. Specifically, the island-like portions IP are disposed around the cut line CL2 in plan view. More specifically, the island-like portions IP are disposed between the cut line CL1 and the cut line CL2 in plan view. Further, the island-like portions IP are disposed away from the cut line CL2.

In the example of FIG. 5, each of the island-like portions IP is located at a respective corner portion CN of the cut line CL1. The corner portion CN is formed of a straight portion extending along the first direction X and a straight portion extending along the second direction Y of the cut line CL1. In FIG. 5, each of the island-like portions IP is indicated by a diagonal pattern.

In this embodiment, four island-like portions IP are arranged for one panel portion PP. Note that the number and position of island-like portions IP disposed for each panel portion PP may be appropriately changed.

The island-like portion IP protrudes in the third direction Z within the margin area FA further from the portions other than the island-like portion IP. In other words, the island-like portion IP has a thickness greater than that of the portions other than the island-like portion in the margin area FA. The island-like portion IP is formed by stacking multiple layers (for example, sealing layers SE1x and SE2, and a resin layer RS3, which will be described later) above the partition 7.

Each island-like portion IP has a similar shape centered around the display area DA, for example. Further, the shape of the island-like portion IP in plan view is not limited to that of the example in FIG. 5. The shapes of the island-like portions IP may differ from one another. Here, focusing on one island-like portion IP (island-like portion IP1 in FIG. 5), the shape of the island-like portion IP in plan view will be described.

The island-like portion IP1 has edges M1, M2, and M3. In other words, the island-like portion IP1 has side surfaces that include the edges M1, M2, and M3, respectively. Thes side surfaces extend upward from the substrate 10. The edge M1 extends in the first direction X. The edge M2 extends in the second direction Y. The length of the edge M1 is approximately equal to the length of, for example, the edge M2.

The edge M3 extends in a direction different from both the first direction X and the second direction Y. Specifically, the edge M3 is formed along the cut line CL2. In the example of FIG. 5, the edge M3 may be formed into a curved line or a straight line. These edges M1, M2, and M3 are connected to each other by short edges SM that are shorter than the edges M1, M2, and M3. Note that the edges M1, M2, and M3 may as well be directly connected to each other.

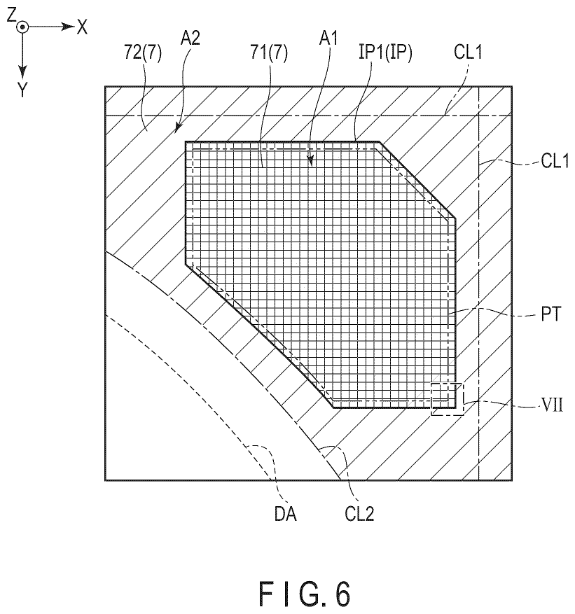

Focusing now on the island-like portion IP1 and its vicinity in FIG. 5, the configuration of the margin area FA will be explained. FIG. 6 is a schematic plan view showing the island-like portion IP1 and its vicinity. As described above, the partition 7 is disposed in the margin area FA.

The partition 7 has multiple segments 71 and 72. In this embodiment, the segment 71 corresponds to a first segment, and the segment 72 corresponds to a second segment. In the margin area FA, the segment 71 is disposed on the island-like portion IP, while the segment 72 is disposed on the regions other than the island-like portions IP.

Here, in the margin area FA, the area where the island-like portion IP is disposed is defined as an area A1, and the area surrounding the island-like portion IP is defined as an area A2. In this embodiment, the area A1 corresponds to a first area, and the area A2 corresponds to a second area. The margin area FA includes, for example, a plurality of areas A1 and an area A2. In FIG. 6, the area A1 is provided with a grid pattern, and the area A2 is provided with a diagonal line pattern. In this embodiment, the area A1 corresponds to the area where the segment 71 is placed, and the area A2 corresponds to the area where the segment 72 is placed.

As shown in FIG. 6, the area A2 is formed so as to surround the area A1. Note that the segment 72 may as well be placed in the peripheral area SA between the cut line CL2 and the display area DA.

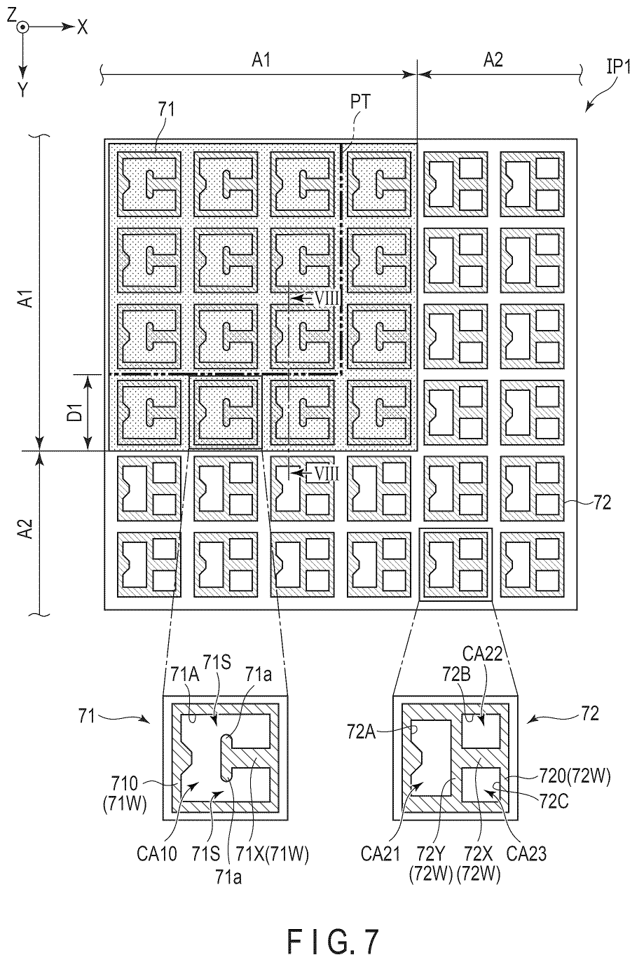

FIG. 7 is a schematic enlarged view showing the portion VII in FIG. 6. As described above, the partition 7 has a plurality of segments 71 disposed in the area A1 and a plurality of segments 72 disposed in the area A2. The segments 71 and 72 are arranged at intervals along the first direction X and the second direction Y.

Here, the planar shapes of the segments 71 and 72 will not be described.

The segments 72 have a planar shape different from that of the segments 71. The outer shapes of the segments 71 and 72 are quadrangular. Here, the term “quadrangular” includes not only square shapes but also rectangular shapes and the like. Further, the corners of the segments 71 and 72 need not be right angles, but they may as well be rounded (R-shaped).

The area of the segments 71 is, for example, equal to the area of the segments 72. The areas of the segments 71 and 72 correspond to the area of the outer shapes thereof in plan view. Note that the area of the segments 71 may be different from that of the segments 72.

The segments 71 each have the same planar shape. The segments 72 each have the same planar shape. The segments 71 and 72 have wall portions 71W and 72W, respectively, as shown in the lower section of FIG. 7. In this embodiment, the wall portions 71W corresponds to first wall portions, and the wall portions 72W corresponds to second wall portions. The wall portions 71W and 72W form respective closed areas, which will be described later.

The wall portions 71W each have a frame-like outer wall 710 and an inner wall 71X extending in a direction opposite to that of the first direction X from the outer wall 710. The inner wall 71X does not divide the interior of the outer wall 710. The segments 71 each have a partition aperture 71A defined by the respective outer wall 710 and the respective inner wall 71X. The area on an inner side of the partition aperture 71A corresponds to a closed area CA10 (a first closed area). In other words, the segment 71 has the closed area CA10.

The planar shape of the partition aperture 71A (closed area CA10) is U-shaped. Further, in the example of FIG. 7, protruding portions 71a respectively extending in the second direction Y and in a direction opposite to the second direction Y are formed at end portions of the inner wall 71X. Between the end portions of the inner wall 71X (protruding portions 71a) and the outer wall 710, slits 71S are respectively formed. Note that the protruding portions 71a may not be formed.

The wall portion 72W has a frame-like outer wall 720, an inner wall 72X extending from the outer wall 720 in the direction opposite to the first direction X, and an inner wall 72Y extending in the second direction Y. The inner wall 72Y divides the interior of the outer wall 710. The inner wall 72X extends in the second direction Y from the outer wall 720 to the inner wall 72Y.

The segment 72 has partition apertures 72A, 72B, and 72C defined by the outer wall 720 and the inner walls 72X and 72Y, respectively. The regions on the inner sides of the partition apertures 72A, 72B, and 72C correspond to the closed areas CA21, CA22, CA23 (second closed areas), respectively. In other words, the segments 72 each have the closed areas CA21, CA22, and CA23.

The planar shapes of the partition apertures 72A, 72B, and 72C (closed areas CA21, CA22, and CA23) are the same as the planar shapes of the partition apertures 601A, 602A, and 603A shown in FIG. 2, respectively. The planer shapes of the partition apertures 72A, 72B, and 72C are, for example, quadrangular.

In the example of FIG. 7, the partition apertures 72B and 72C are aligned with the partition aperture 72A along the first direction X. Further, the partition apertures 72B and 72C are aligned along the second direction Y. Further, the partition apertures 72B and 72C are smaller than the partition aperture 71A. Note that the shapes and positions of the partition apertures 72A, 72B, and 72C are not limited to those of the example shown in FIG. 7.

Compared to the segment 71, the planar shapes of the closed areas CA21, CA22, and CA23 of the segment 72 are different from the planar shape of the closed area CA10 of the segment 71. The segment 72 has more closed areas CA21, CA22, and CA23 than the closed areas CA10 of the segment 71. In this embodiment, the segment 71 has one closed area, whereas the segment 72 has a plurality of (for example, three) closed areas.

The area of the closed area CA10 of the segment 71 is larger than the area of each of the closed areas CA21, CA22, and CA23 of the segment 72. From another perspective, the ratio of the area of the closed area CA10 to the area of the segment 71 is greater than the ratio of the total area of the closed areas CA21, CA22, and CA23 to the area of the segment 72.

The area of the wall portion 72W of the segment 72 is larger than the area of the wall portion 71W of the segment 71. From another perspective, the ratio of the area of the wall portion 71W to the area of the segment 71 is smaller than the ratio of the area of the wall portion 72W to the area of the segment 72.

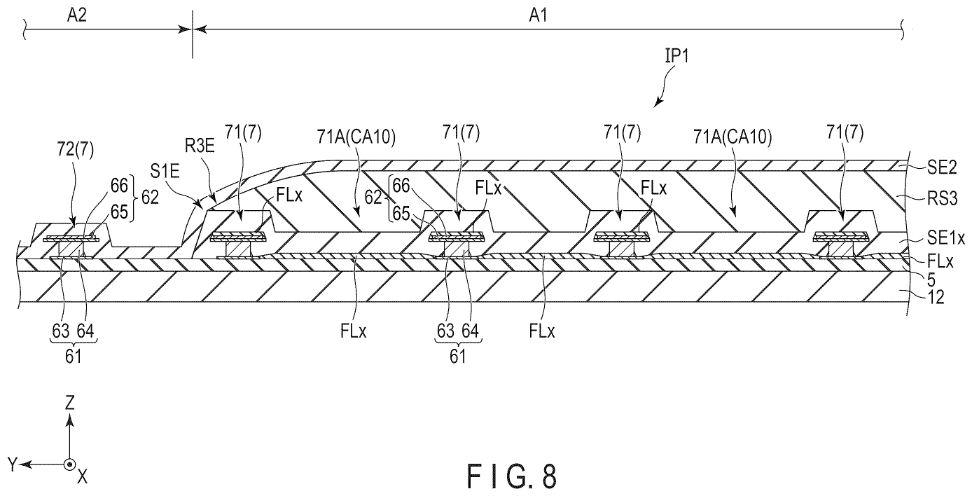

FIG. 8 is a schematic cross-sectional view taken along the line VIII-VIII in FIG. 7. In FIG. 8, the partition 7 is viewed in the direction opposite to the first direction X.

The organic insulating layer 12 and rib layer 5, described above are formed in the peripheral area SA, including the margin area FA, as well. In FIG. 8, the elements located below the organic insulating layer 12 are omitted.

The partition 7 (the segments 71, and 72) is disposed on the rib layer 5. The segments 71 and 72 each have a similar cross-sectional structure. As in the case of the partition 6, the segments 71 and 72 each include a lower portion 61 and an upper portion 62. In this embodiment, the lower portion 61 of the partition 7 corresponds to a first lower portion, and the upper portion 62 of the partition 7 corresponds to a first upper portion.

The upper portion 62 has a width larger than that of the lower portion 61. The lower portion 61 of the partition 7, as in the case of the partition 6, includes a bottom layer 63 and an axial layer 64. The upper portion 62 of the partition 7, as in the case of the partition 6, includes a first top layer 65 and a second top layer 66.

The bottom layer 63, axial layer 64, first top layer 65, and second top layer 66 of the partition 7 are formed from the same materials as those of the bottom layer 63, axial layer 64, first top layer 65, and second top layer 66 of the partition 6, respectively.

The stacked multilayer film FLx is disposed in the area A1 (island-like portion IP) in the margin area FA and is not disposed in the area A2. In the area A1, the stacked multilayer film FLx is disposed on the wall portion 71W of the segment 71, on the rib layer 5 of the closed area CA10 of the segment 71, and on the rib layer 5 between each adjacent pair of segments 71.

The stacked multilayer film FLx is formed by the same process and of the same material as those of any one of the stacked multilayer films FL1, FL2, and FL3 shown in FIG. 3. In other words, the stacked multilayer film FLx is constituted by the same layer as that of any one of the stacked multilayer films FL1, FL2, and FL3. The stacked multilayer film FLx is formed, for example, by the same process and of the same material as those of the stacked multilayer film FL3. Therefore, the cap layer CP3 is disposed in the margin area FA as well.

The sealing layer SE1x is disposed in the area A1 (island-like portion IP) in the margin area FA and is not disposed in the area A2. For example, the end of the sealing layer SE1x corresponds to the end of the area A1. The sealing layer SE1x is placed on the stacked multilayer film FLx. The stacked multilayer film FLx is disposed between the segment 71 and the sealing layer SE1x.

The sealing layer SE1x continuously covers the divided portions of the stacked multilayer film FLx and the partition 7. Focusing on the segment 71, the sealing layer SE1x is in contact with the lower portion 61 and upper portion 62 of the segment 71. With this configuration, the segment 71 is not exposed from the sealing layer SE1x. In contrast, the sealing layer SE1x is not disposed above the segment 72.

The sealing layer SE1x is formed by the same process and of the same material as those of one of the sealing layers SE11, SE12, and SE13 shown in FIG. 3. Th sealing layer SE1x is formed by the same process and of the same material as those of the sealing layer SE13. In this embodiment, the sealing layers SE11, SE12, SE13, and SE1x correspond to the first sealing layer.

The resin layer RS3 is disposed in the area A1 (island-like portion IP) within the margin area FA and is not disposed in the area A2. The resin layer RS3 is placed on the sealing layer SE1x. The resin layer RS3 is formed by the same process and of the same material as those of the resin layer RS1 of the display area DA (shown in FIG. 3). The island-like portion IP includes the segment 71, the stacked multilayer film FLx, the sealing layer SE1x, the resin layer RS3, and the sealing layer SE2.

The thickness of the resin layer RS3 is less than the thickness of the resin layer RS1, for example, (shown in FIG. 3). Further, the island-like portion IP (resin layer RS3) is separated from the resin layer RS1. In other words, the resin layer RS3 is disconnected from the resin layer RS1.

Focusing on the end portion S1E of the sealing layer SE1x, the end portion R3E of the resin layer RS3 is located on the sealing layer SE1x. Here, the end portion includes the end and its vicinity area. The end portion R3E overlaps the end portion S1E. In other words, the resin layer RS3 does not protrude beyond the end portion S1E. Further, the resin layer RS3 is not disposed above the segment 72.

Note that the position of the end portion R3E of the resin layer RS3 is not limited to that of the example in FIG. 8. The end portion R3E may be disposed on an inner side of the island-like portion IP1, for example, relative to that of the example in FIG. 8. Further, although the end portion R3E is disposed above the segment 71 of the partition 7, it need not be disposed above the segment 71.

The sealing layer SE2 is disposed in each of the areas A1 and A2. In this embodiment, the sealing layer SE2 corresponds to the second sealing layer. Focusing on the area A1, the sealing layer SE1x and resin layer RS3 are each covered by the sealing layer SE2. The segment 71 is not in contact with the sealing layer SE2. Focusing on the area A2, the rib layer 5 and the segment 72 are covered by the sealing layer SE2.

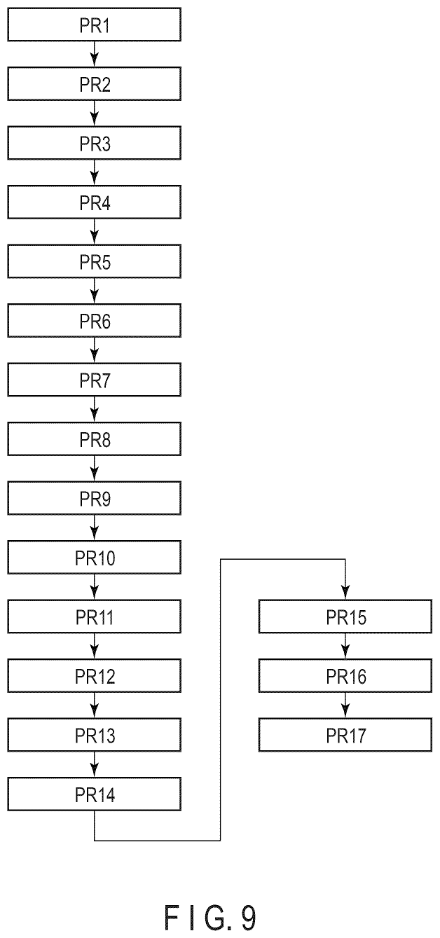

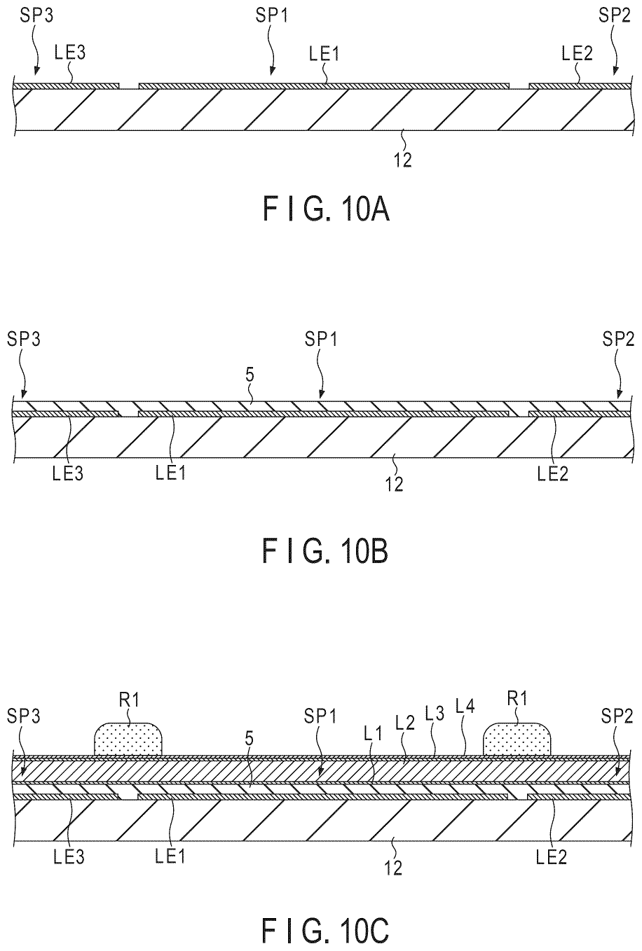

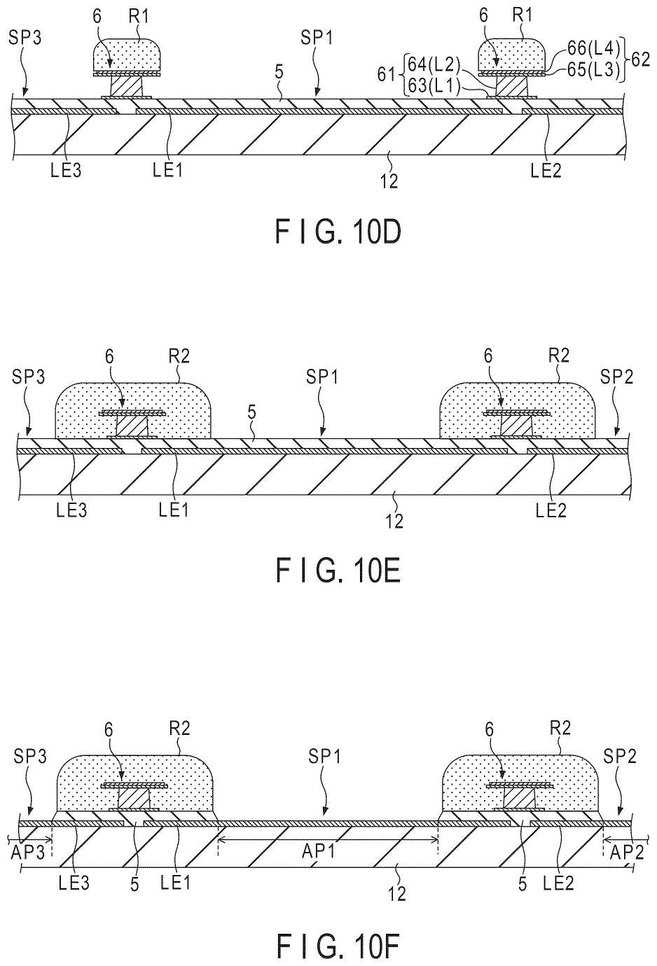

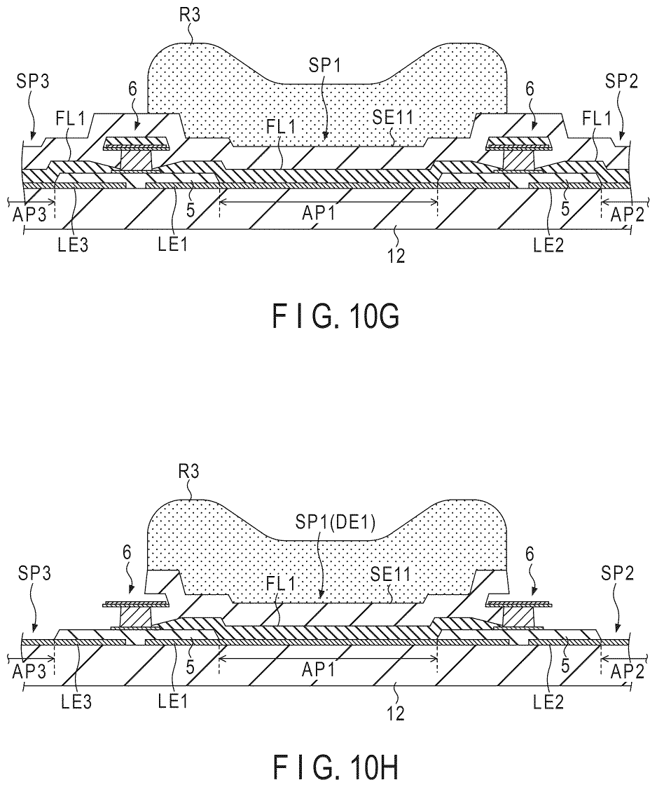

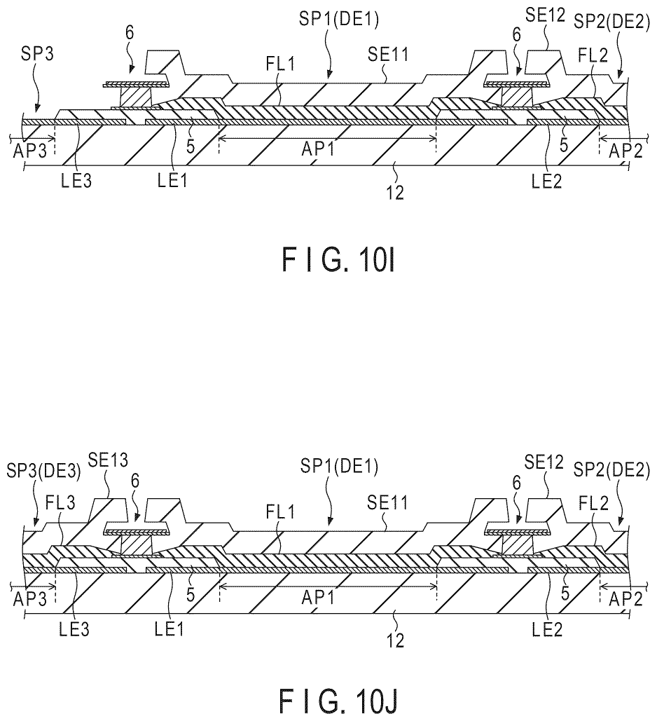

Next, an example of a method of manufacturing the display device DSP will be described. FIG. 9 is a flowchart showing an example of the method of manufacturing the display device DSP. FIGS. 10A to 10J are schematic cross-sectional views each showing a processing step of the manufacturing of the display device DSP. In FIGS. 10A to 10J, the focus is primarily on the display area DA, and elements located below the organic insulating layer 12 are omitted.

In the formation of the panel portion PP, the substrate 10 of the mother board MB is prepared, and the circuit layer 11 and the organic insulating layer 12 are formed (processing step PR1 in FIG. 9). Next, as shown in FIG. 10A, the lower electrodes LE1, LE2, and LE3 are formed on the organic insulating layer 12 (processing step PR2 in FIG. 9).

Subsequently, as shown in FIG. 10B, the rib layer 5, which covers the lower electrodes LE1, LE2, and LE3, is formed over the entire mother board MB (processing step PR3 in FIG. 9). At this stage, the pixel apertures AP1, AP2, and AP3 are not yet provided in the rib layer 5. The rib layer 5 can be formed by chemical vapor deposition (CVD).

After the formation of the rib layer 5, a processing step to form the partition 6 is carried out (processing step PR4 in FIG. 9). In the processing step PR4, as shown in FIG. 10C, a first layer L1 which will be processed into the bottom layer 63, a second layer L2 to be processed into the axial layer 64, a third layer L3 to be processed into the first top layer 65, and a fourth layer L4 to be processed into the second top layer 66 are sequentially formed over the entire mother board MB. Further, a resist R1 is placed on the fourth layer L4. The resist R1 is patterned into the shape of the partition 6. The first layer L1, second layer L2, third layer L3, and fourth layer L4 can be formed, for example, by sputtering.

After that, using the resist R1 as a mask, the first layer L1, second layer L2, third layer L3, and fourth layer L4 are patterned. In one example, the first layer L1 is formed from titanium nitride, the second layer L2 is formed from aluminum, the third layer L3 is formed from titanium, and the fourth layer L4 is formed from ITO. With this configuration, the patterning may include wet etching to remove the portions of the fourth layer L4, which are exposed from the resist R1, dry etching to remove the portions of the first layer L1, second layer L2, and third layer L3, which are exposed from the resist R1, and wet etching to reduce the width of the second layer L2.

After the processing step PR4, as shown in FIG. 10D, the partition 6 is formed in the display area DA. After the formation of the partition 6, the resist R1 is removed (peeled off). During the above-mentioned wet etching that reduces the width of the second layer L2, the second top layer 66 (fourth layer L4) may also be slightly eroded. If this erosion occurs, the width of the second top layer 66 becomes smaller than the width of the first top layer 65.

Next, a process to form the pixel apertures AP1, AP2, and AP3 is carried out (processing step PR5 in FIG. 9). In this processing step PR5, as shown in FIG. 10E, a resist R2, which covers the partition 6, is formed. Furthermore, using the resist R2 as a mask, dry etching is performed on the rib layer 5. In this manner, the pixel apertures AP1, AP2, and AP3 are formed in the rib layer 5, which expose the lower electrodes LE1, LE2, and LE3, respectively, as shown in FIG. 10F. After the above-mentioned dry etching, the resist R2 is removed (peeled off).

After the processing step PR5, a process is performed to remove the rib layer 5 located at the inspection pads in the margin area FA (processing step PR6 in FIG. 9). In the processing step PR6, the resist opened at the inspection pads is placed on the rib layer 5, and dry etching is performed on the rib layer 5.

After the processing step PR6, a process to form the display element DE1 is carried out (processing step PR7 in FIG. 9). In the formation of the display element DE1, first, as shown in FIG. 10G, the stacked multilayer film FL1 and the sealing layer SE11 are formed. The stacked multilayer film FL1 includes, as shown in FIG. 3, an organic layer OR1 brought into contact with the lower electrode LE1 through the pixel aperture AP1, an upper electrode UE1 covering the organic layer OR1, and a cap layer CP1 covering the upper electrode UE1. The organic layer OR1, the upper electrode UE1, and the cap layer CP1 can be formed, for example, by vapor deposition. Further, the sealing layer SE11 can be formed, for example, by CVD.

The stacked multilayer film FL1 and the sealing layer SE11 are formed over the entire mother board MB, including not only the portions of the display area DA, which correspond to the panel portions PP but also the peripheral area SA. The stacked multilayer film FL1 is divided into a plurality of portions by the overhanging partition 6. The sealing layer SE11 continuously covers the divided portions of the stacked multilayer film FL1 and the partition 6.

Next, the stacked multilayer film FL1 and sealing layer SE11 are patterned. In this patterning, as shown in FIG. 10G, a resist R3 is disposed on the sealing layer SE11. The resist R3 covers the subpixel SP1 and part of the partition 6 therearound.

Subsequently, an etching process using the resist R3 as a mask is carried out. With this configuration, the portions of the stacked multilayer film FL1 and sealing layer SE11, which are exposed from the resist R3 are removed, as shown in FIG. 10H. In other words, the portions of the stacked multilayer film FL1 and sealing layer SE11, which overlap the lower electrode LE1 are left to remain, whereas the other portions are removed. With this configuration, the display element DE1 is formed in the subpixel SP1. For example, in the peripheral area SA, the stacked multilayer film FL1 and sealing layer SE11 are removed by this etching process. This etching process may include wet etching or dry etching performed sequentially on the sealing layer SE11, cap layer CP1, upper electrode UE1, and organic layer OR1. After the etching of these members, the resist R3 is removed (peeled off).

After the processing step PR7, a process to form the display element DE2 is carried out (processing step PR8 in FIG. 9). The display element DE2 can be formed by the same procedure as that of the display element DE1. That is, in the formation of the display element DE2, the stacked multilayer film FL2 and sealing layer SE12 are formed over the entire mother board MB. The stacked multilayer film FL2 includes, as shown in FIG. 3, an organic layer OR2 contacting the lower electrode LE2 through the pixel aperture AP2, an upper electrode UE2 covering the organic layer OR2, and a cap layer CP2 covering the upper electrode UE2.

The organic layer OR2, upper electrode UE2, and cap layer CP2 can be formed, for example, by vapor deposition. Further, the sealing layer SE12 can be formed, for example, by CVD. The stacked multilayer film FL2 is divided into a plurality of portions by the overhanging partition 6. The sealing layer SE12 continuously covers the divided portions of the stacked multilayer film FL2 and the partition 6. By patterning the stacked multilayer film FL2 and sealing layer SE12 having such a configuration, the display element DE2 is formed in the subpixel SP2, as shown in FIG. 10I. For example, in the peripheral area SA, the stacked multilayer film FL2 and sealing layer SE12 are removed by etching during this patterning.

After the processing step PR8, a process to form the display element DE3 is carried out (processing step PR9 in FIG. 9). The display element DE3 can be formed by the same procedure as those of the display elements DE1 and DE2. That is, in the formation of the display element DE3, the stacked multilayer film FL3 and sealing layer SE13 are formed over the entire mother board MB. The stacked multilayer film FL3 includes, as shown in FIG. 3, an organic layer OR3 brought into contact with the lower electrode LE3 through the pixel aperture AP3, an upper electrode UE3 covering the organic layer OR3, and a cap layer CP3 covering the upper electrode UE3.

The organic layer OR3, upper electrode UE3, and cap layer CP3 can be formed, for example, by vapor deposition. Further, the sealing layer SE13 can be formed, for example, by CVD. The stacked multilayer film FL3 is divided into a plurality of portions by the overhanging partition 6. The sealing layer SE13 continuously covers the divided portions of the stacked multilayer film FL3 and the partition 6. By patterning the stacked multilayer film FL3 and sealing layer SE13 having such a configuration, the display element DE3 is formed in the subpixel SP3, as shown in FIG. 10J. For example, in the peripheral area SA, parts of the stacked multilayer film FL3 and sealing layer SE13 are removed by etching during this patterning.

Note here that, in the regions of the margin region FA, where a plurality of island-like portions IP are formed, the stacked multilayer film FL3 and sealing layer SE13 are left to remain without being removed by etching. These remaining stacked multilayer film FL3 and sealing layer SE13 correspond respectively to the stacked multilayer film FLx and sealing layer SE1x shown in FIG. 8.

Note that it is assumed here that the display elements DE1, DE2, DE3 are formed in this order, but the display elements DE1, DE2, DE3 may be formed in some other order.

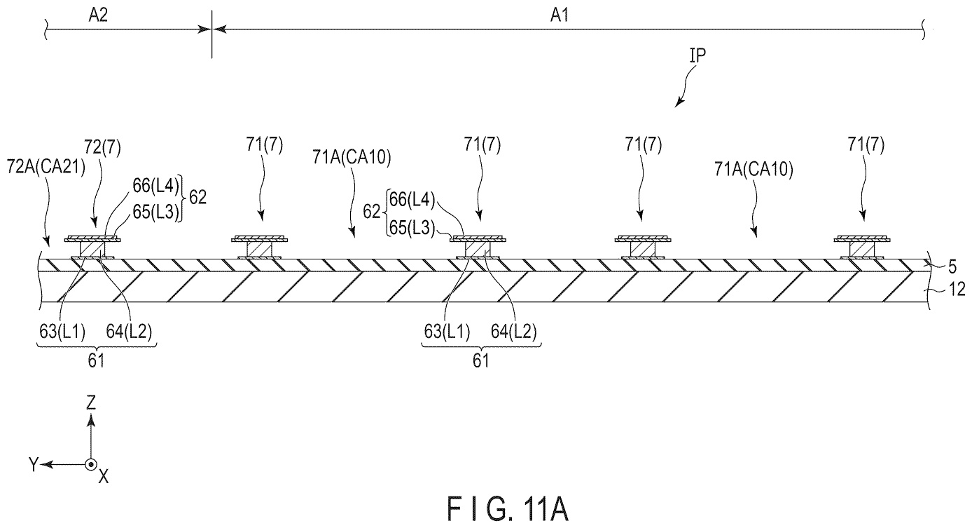

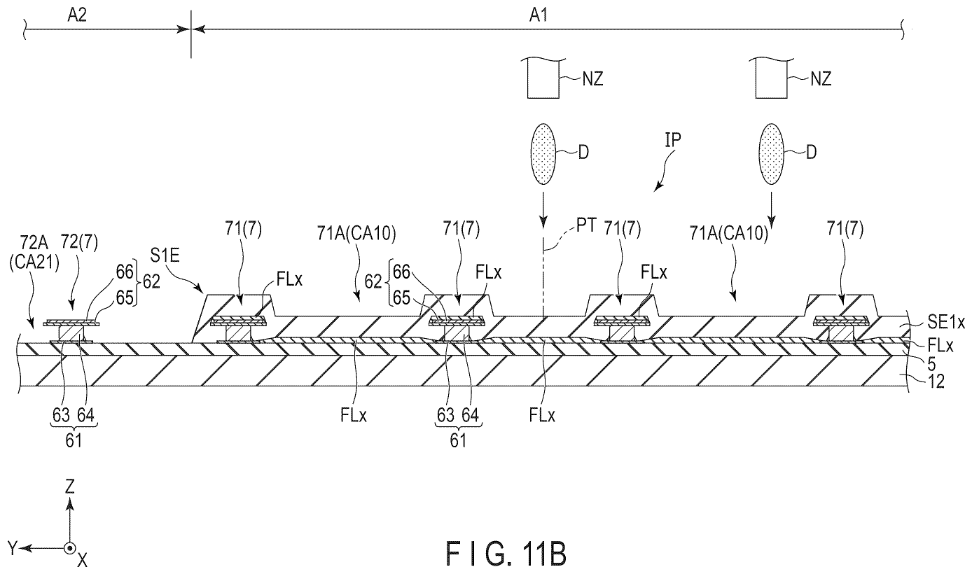

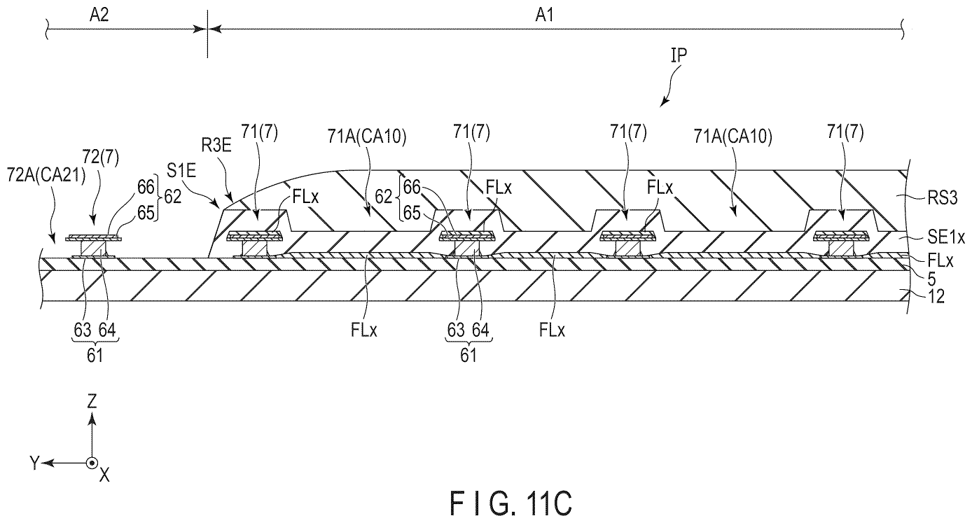

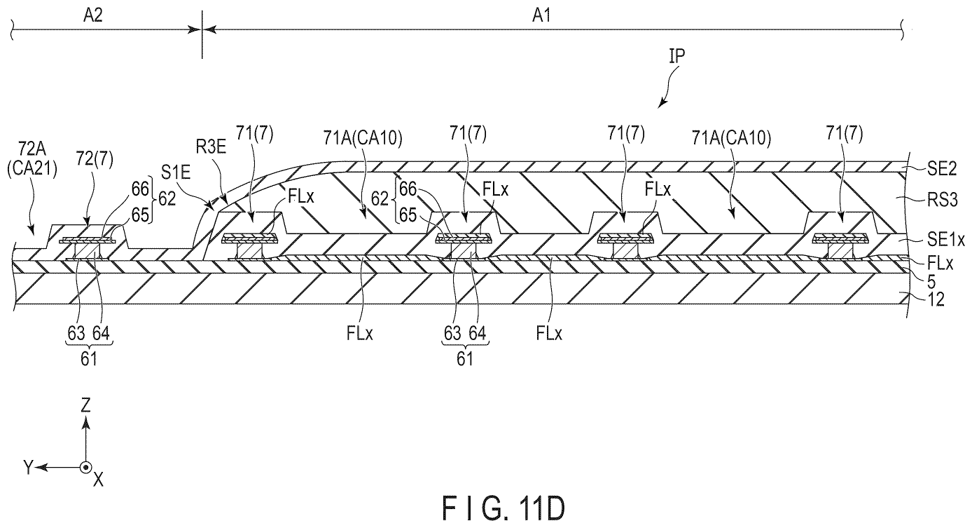

FIGS. 11A to 11D are schematic cross-sectional views each showing the structure of the margin area FA during the manufacturing process of the display device DSP.

The partition 7 (segments 71 and 72) of the margin area FA is formed together with the partition 6 in the processing step PR4. After the processing step PR4, the overhanging segments 71 and 72, each having a lower portion 61 and an upper portion 62, are formed as shown in FIG. 11A. The bottom layer 63, axial layer 64, first top layer 65, and second top layer 66 of these segments 71, 72 are respectively processed from the above-mentioned first layer L1, second layer L2, third layer L3, and fourth layer L4.

Further, after the processing step PR9, the stacked multilayer film FLx and sealing layer SE1x are formed in the area A1 (island-like portion IP), as shown in FIG. 11B. As explained with reference to FIG. 8, the stacked multilayer film FLx is formed on the wall portion 71W of the segment 71, in the closed area CA10 of the segment 71, and between adjacent segments 71. By contrast, in the area A2, the stacked multilayer film FLx and the sealing layer SE1x are not formed. Thus, in the margin area FA, the stacked multilayer film FLx and sealing layer SE1x are formed by patterning the stacked multilayer film FL3 and sealing layer SE13.

As described above, the stacked multilayer film FLx is finely divided by the segments 71. With this configuration, the divided portions of the stacked multilayer film FLx and the sealing layer SE1x covering these portions are peeled off from the underlayer.

After the processing step PR9, a process to form the resin layer RS1 is carried out (processing step PR10 in FIG. 9). The resin layer RS1 can be formed on an inner side of the dam structure DS (shown in FIG. 1) by, for example, an inkjet method. The dam structure DS serves to contain the uncured resin layer RS1. The processing step PR10 includes a plurality of (for example, three) coating steps.

Further, in the processing step PR10 of FIG. 9, a resin layer RS3 is formed on the sealing layer SE1x of the island-like portion IP, as shown in FIG. 11C. The resin layer RS3 is formed in the margin area FA (between the cut line CL1 and cut line CL2). Specifically, the resin layer RS3 is formed at the corner CN of the cut line CL1 (shown in FIG. 5).

More specifically, the resin layer RS3 is formed in the area A1. The resin layer RS3 is formed to be thinner than the resin layer RS1. Specifically, the resin layer RS3 is formed with a less number of layers than that of the resin layer RS1. In contrast, the resin layer RS3 is not formed in the area A2.

The droplets D which forms the resin layer RS3 are ejected from a nozzle NZ toward the sealing layer SE1x, as shown in FIG. 11B. FIG. 11B shows the droplets D being ejected toward the mother board MB during the above-described processing step PR10 when the resin layer RS3 is formed by inkjet printing.

The outer edge of the range where the droplets D are ejected is located at the portion overlapping with the sealing layer SE1x. In FIGS. 6 and 7, the outer edge of the range where the droplets D are ejected is shown as an inkjet pattern PT. The droplets D are ejected onto the inner side of the inkjet pattern PT.

As shown in FIG. 6, focusing on one island-like portion IP, the area of the inkjet pattern PT is smaller than the area of the island-like portion IP (area A1). Further, as shown in FIG. 7, a plurality of segments 71 are disposed on an outer side of the inkjet pattern PT, so as to surround the pattern.

For example, in the second direction Y, at least one segment 71 is disposed between the segment 71 and segment 72 located at the outermost side overlapping the inkjet pattern PT. Similarly, in the first direction X, at least one segment 71 is disposed between the segment 71 and segment 72 located at the outermost side overlapping the inkjet pattern PT. The distance (distance D1 shown in FIG. 7) between the inkjet pattern PT and the edge of the sealing layer SE1 x is, for example, approximately 100 μm.

The droplets D ejected from the nozzle NZ spread over the sealing layer SE1x, thereby forming the resin layer RS3. At this time, the spreading of the resin layer RS3 is suppressed by surface tension near the end portion S1E. Therefore, the sealing layer SE1x becomes larger than the inkjet pattern PT and is less likely to protrude from the upper surface of the sealing layer SE1x.

When the droplets D are ejected onto the sealing layer SE1x in the above-described manner, the resin layer RS3 can be disposed at the intended location. In other words, the sealing layer SE1x functions to position the resin layer RS3. In FIG. 7, a dot pattern is applied to the area where the resin layer RS3 is formed.

After the processing step PR10, the sealing layer SE2 is formed over the entire mother board MB, for example, by CVD (processing step PR11 in FIG. 9). The sealing layer SE1x and resin layer RS3 of the island-like portion IP are covered by the sealing layer SE2, as shown in FIG. 11D. Further, the segment 72 and rib layer 5 in the area A2 are covered by the sealing layer SE2.

With the above-described configuration, the island-like portions IP are formed in the margin area FA, as shown in FIG. 5. By forming the island-like portions IP in the margin area FA in the above-described manner, variations in the thickness of the resist applied in subsequent steps, for example can be suppressed. Specifically, when the island-like portions IP are disposed in the margin area FA, the difference in the flow velocity of the resist across the panel portion PP can be reduced, and thus the non-uniformity of coating of the resist can be suppressed. As a result, the resist reliably functions as a mask, the removal of layers disposed below the resist can suppressed, thereby reducing the likelihood of occurrence of defects in the manufactured display device DSP.

After the processing step PR11, a process is performed to remove the rib layer 5 and sealing layer SE2 covering the terminal portion T (processing step PR12 in FIG. 9). Further, a process is performed to remove the sealing layer SE2 surrounding the terminal portion T (processing step PR13 in FIG. 9).

After the processing step PR13, a touch panel electrode TP is formed on the sealing layer SE2 (processing step PR14 in FIG. 9). Specifically, first, a conductive layer to be processed into the touch panel electrode TP is formed over the entire mother board MB. Next, a resist having a shape corresponding to the touch panel electrode TP is placed, and using this resist as a mask, the conductive layer is etched. After this etching, the resist is removed (peeled off).

After the processing step PR14, a resin layer RS2 is formed (processing step PR15 in FIG. 9). The resin layer RS2 can be formed on an inner side of the dam structure DS, for example, using an inkjet method. The dam structure DS serves to contain the uncured resin layer RS2.

The resin layer RS2 may as well be formed by a photolithography process. In this case, a photosensitive resin for forming the resin layer RS2 is first formed over the entire mother board MB. Then, through the processes of pre-baking, exposure, development, and baking of this photosensitive resin, the resin layer RS2 is formed in each of the panel portions PP.

After the processing step PR15, each panel portion PP is cut out from the mother board MB along the cut line CL1 (processing step PR16 in FIG. 9). Further, the margin area FA is cut along the cut line CL2 (processing step PR17 in FIG. 9). In this manner, the display panel PNL is completed.

As in this embodiment, in the formation of a resin layer RS3 in the margin area FA, as described above, the droplets D are ejected onto the sealing layer SE1x pre-disposed, and thus the spreading of the droplets D are suppressed by the sealing layer SE1x, thereby making it possible to place the resin layer RS3 at the desired position.

Depending on the shape of the closed area (partition aperture) of the partition disposed below the sealing layer SE1x, air may remain in this closed area when the droplets D are ejected. As a result, such areas where the droplets D do not sufficiently flow may be created in the island-shaped portion IP. Consequently, this can cause the creation of areas where the resin layer RS3 is not formed (coating missing areas) in part of the island-shaped portion IP.

In this embodiment, the segment 71 of the partition 7 is disposed in the island-like portion IP. Specifically, the segment 71 has one closed area CA10 which has not been divided out. Compared to the segment 72, the area of the closed area CA10 is larger than the closed areas CA21, CA22, and CA23 of the segment 72.

With the above-described configuration, when the ejected droplets D flow, air can easily escape from the closed area CA10, allowing the droplets D to sufficiently spread within the closed area CA10. Specifically, because the closed area CA10 is not divided, once droplets D enter the closed area CA10, they can flow throughout the entire closed area CA10. In this manner, areas where the resin layer RS3 is not formed are not easily created in the island-like portion IP, thus making it possible to disposed the resin layer RS3 over the entire island-like portion IP.

Note that when the segment 71 is placed in the area other than the island-like portion IP (area A2), some other issues may arise. That is, because the closed area CA10 of the segment 71 is large, when the sealing layer SE2 is placed on the segment 71 in the area A2, sufficient adhesion with the sealing layer SE2 may not be ensured, which may potentially cause the sealing layer SE2 to peel off.

Regarding this point, in this embodiment, the segment 72 of the partition 7 is placed in the area other than the island-like portions IP (area A2). Specifically, the segment 72 has partition apertures 72A, 72B, and 72C, which are divided into multiple.

With this configuration, the sealing layer SE2 is disposed such as to enter each of the partition apertures 72A, 72B, and 72C. Thus, the adhesion to the substrate can be improved and it is possible to suppress the peeling off of the sealing layer SE2. Further, the area A2 is an area where the resin layer RS3 is not placed, and therefore the area of each of the closed areas CA21, CA22 and CA23 may be smaller than the area of the closed area CA10.

As described above, in the margin area FA, the area A1 (where the segment 71 is disposed) to suppress the occurrence of areas where the resin layer RS3 is not formed, and the area A2 (where the segment 72 is disposed) to suppress the peeling off of the sealing layer SE2 are formed. Thus, when the resin layer RS3 and the sealing layer SE2 are reliably formed in the margin area FA, the yield of the display device DSP can be improved.

In this embodiment, the segments 71 and 72 of the partition 7 are appropriately disposed according to the position, shape, and size of the island-like portion IP disposed in the margin area FA, and therefore the yield of the display device DSP can be improved.

In this embodiment, the sealing layer SE1x is placed within the island-shaped portion IP of the margin area FA. In other words, the area where the sealing layer SE1x is placed is reduced. Thus, by reducing the area where the sealing layer SE1x is placed in this manner, it becomes easier to suppress the peeling off of the sealing layer SE1x.

Next, other embodiments will be described. Note that in the other embodiments described below, components similar to those in the first embodiment described above may be assigned the same reference numerals as those in the first embodiment, and their detailed descriptions may be omitted or simplified. As for configurations of display devices DSP not specifically mentioned, those similar to the configuration of the first embodiment can be applied.

### Second Embodiment

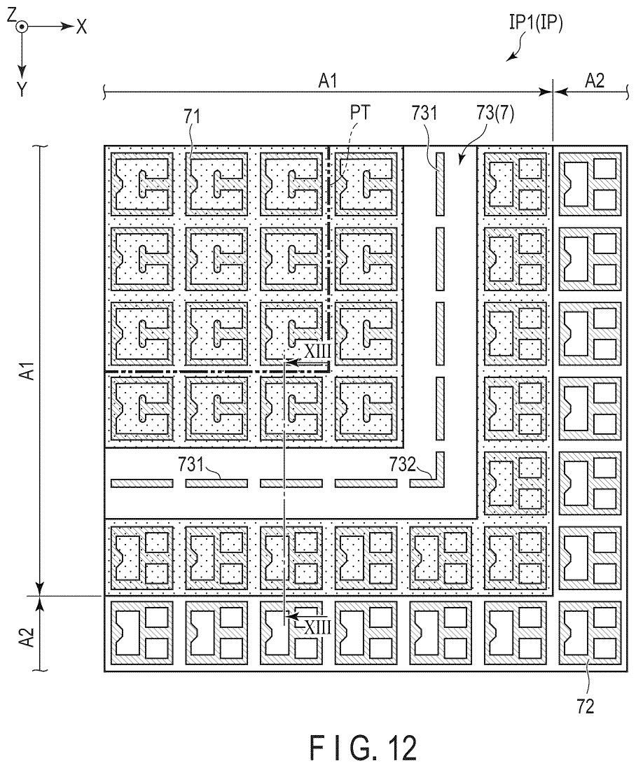

FIG. 12 is a schematic enlarged view showing a part of the display device DSP according to this embodiment. FIG. 12 shows positions similar to those in the FIG. 7 explained above. In this embodiment, the configuration of the island-like portion IP is different from that of the first embodiment. In FIG. 12, a dot pattern is applied to the area where the sealing layer SE1x is formed. The planar shapes of the segments 71 and 72 are similar to those of the first embodiment. The segments 71 and 72 are disposed at intervals along the first direction X and the second direction Y.

The partition 7 further has a plurality of segments 73 (third segments). In this embodiment, the segments 71, 72, and 73 are disposed in the island-like portion IP. In other words, the area A1 corresponds to the area where the segments 71, 72, and 73 are disposed, and the area A2 corresponds to the area where the segment 72 is disposed. The segment 73 is formed together with the segments 71 and 72 in the processing step PR4 of FIG. 9.

The plurality of segments 73 are each disposed between a respective one of the plurality of segments 71 and a respective one of the plurality of segments 72. The plurality of segments 73 are disposed, for example, to enclose the plurality of segments 71. Between each pair of segments 73 adjacent to each other along the first direction X and between each pair of segments 73 adjacent to each other along the second direction Y, gaps are formed, respectively.

The segments 73 have a planar shape different from those of the segments 71 and 72. The segments 73 include straight segments 731 and bent segments 732. The straight segments 731 include segments elongated along the first direction X and segments elongated along the second direction Y. The shapes of these segments are not limited to those of the example described above. For example, segments including curved portions may as well be included.

The interval between a segment 71 and a respective segment 73, and the interval between a segment 73 and a respective segment 72, are larger than the interval between each adjacent pair of segments 71 and the interval between each adjacent pair of segments 72.

In the example shown in FIG. 12, the respective one of the plurality of segments 73 is disposed in the central portion of the figure, between the respective segment 71 and the respective segment 72, but this configuration is not limited to that of this example. When the interval between the respective segment 71 and the respective segment 72 is approximately 100 μm, the interval between the respective segment 71 and the respective segment 73, and the interval between the respective segment 73 and the respective segment 72, are, for example, 30 μm or greater.

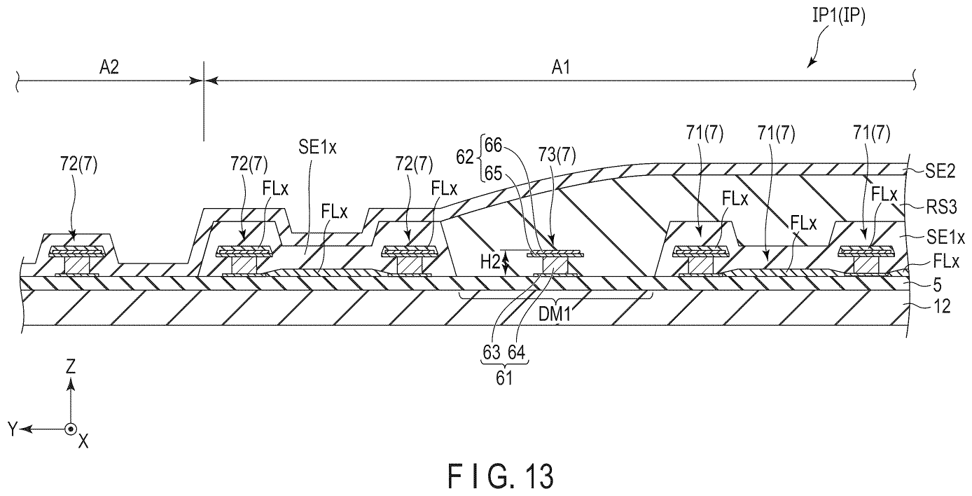

FIG. 13 is a schematic cross-sectional view taken along the line XIII-XIII in FIG. 12. In FIG. 13, the partition 7 is viewed in the direction opposite to the first direction X.

As in the case of the first embodiment, the organic insulating layer 12 and the rib layer 5 are formed in the peripheral area SA as well, including the margin area FA. In FIG. 13, elements below the organic insulating layer 12 are omitted.

The partition 7 (segments 71, 72, and 73) is disposed on the rib layer 5. The segments 73, as in the case of the partition 6, each include a lower portion 61 and an upper portion 62. The upper portion 62 of each segment 73 has a width larger than that of the lower portion 61. The lower portion 61 of each segment 73, as in the case of the partition 6, includes a bottom layer 63 and an axial layer 64. The upper portion 62 of the segment 73 includes a first top layer 65 and a second top layer 66, as in the case of the partition 6.

The bottom layer 63, axial layer 64, first top layer 65, and second top layer 66 of the segment 73 are formed from the same materials as those of the bottom layer 63, axial layer 64, first top layer 65, and second top layer 66 of the partition 6, respectively.

The sealing layer SE1x is disposed in the area A1 (island-like portion IP) within the margin area FA, and is not disposed in the area A2. Specifically, the sealing layer SE1x is disposed so as to cover the segments 71 and 72. In contrast, the sealing layer SE1x is not disposed above the segment 73. In other words, the segment 73 is not covered by the sealing layer SE1x. In this embodiment, for example, the edge of the sealing layer SE1x covering the segment 72 corresponds to the edge of the area A1.

Further, between the sealing layer SE1x covering the respective segment 71 and the sealing layer SE1x covering the respective segment 72, a dam DM1 is formed. The segment 73 is located on an inner side of the dam DM1. The dam DM1 includes the area between each of the segments 71 and each respective one of the segments 73, and the area between each of the segment 73 and each respective one of the segments 72.

Focusing on the stacked multilayer film FLx, it is disposed between the segments 71, 72 and the sealing layer SE1x. By contrast, the stacked multilayer film FLx is not disposed on the respective segment 73.

The resin layer RS3 is disposed in the area A1 (island-like portion IP) within the margin area FA and is not disposed in the area A2. Specifically, the resin layer RS3 is disposed on the sealing layer SE1x, which is disposed above the segment 71.

Further, the resin layer RS3 is disposed above the segment 73 as well. Specifically, the resin layer RS3 is disposed so as to cover the segment 73. In contrast, the resin layer RS3 is not disposed on the sealing layer SE1x, which is disposed above the segments 72. In other words, the sealing layer SE1x, disposed above the segments 72, is in contact with the sealing layer SE2.

The resin layer RS3 is formed by the same process and of the same material as those of the resin layer RS1 (shown in FIG. 3) in the display area DA. The range in which the material for forming the resin layer RS3 is applied is the same as that of the first embodiment, for example.

The dam DM1 serves to contain the uncured resin layer RS3. Therefore, even in the case where an application misalignment occurs during the manufacturing process, the uncured resin layer RS3 is contained by the dam DM1. The island-like portion IP includes the segments 71, 72, and 73, stacked multilayer film FLx, sealing layer SE1x, resin layer RS3, and sealing layer SE2.

With this embodiment, advantageous effects similar to those of the first embodiment can be obtained. In this embodiment, the dam DM1 is formed within the island-like portion IP. With this configuration, the uncured resin layer RS3 is contained by the dam DM1, thus making it possible to facilitate the formation of the resin layer RS3 within the desired range. Further, by placing the segment 73 in the dam DM1, it is possible to suppress the area where the dam DM1 is formed from becoming a starting point in film peeling.

Note that the example shown in FIG. 13 discloses the case where the dam DM1 is filled with the resin layer RS3, but the dam DM1 may not necessarily be filled with the resin layer RS3.

### Third Embodiment

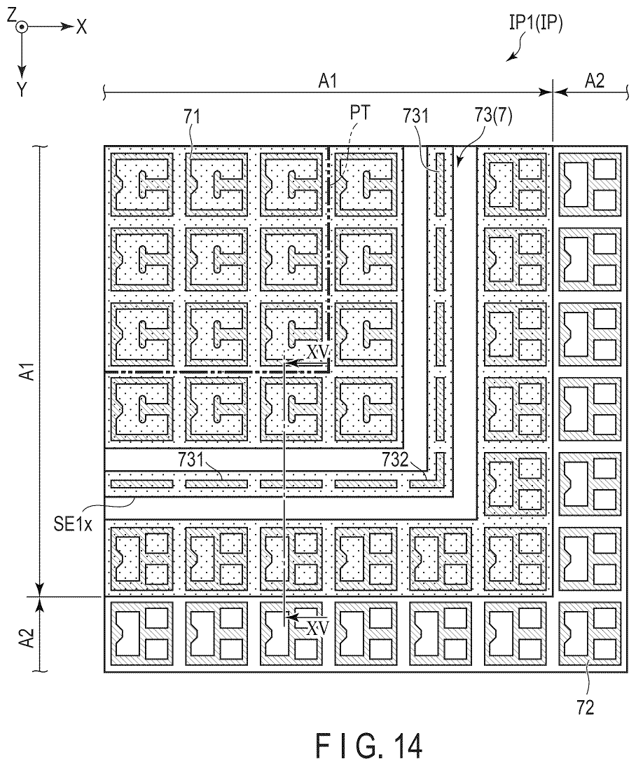

FIG. 14 is a schematic enlarged view showing a part of a display device DSP according to this embodiment. This embodiment is different from the second embodiment in that the segments 73 is covered by the sealing layer SE1x.

In this embodiment, a plurality of segments 73 covered by the sealing layer SE1x are disposed to surround a plurality of segments 71, respectively. The sealing layer SE1x continuously covers the plurality of segments 73. Specifically, the sealing layer SE1x is disposed in the gap between each adjacent pair of segments 73. Note that the plurality of segments 73 are configured to be similar to that of the second embodiment, but the configuration is not limited to that of this example.

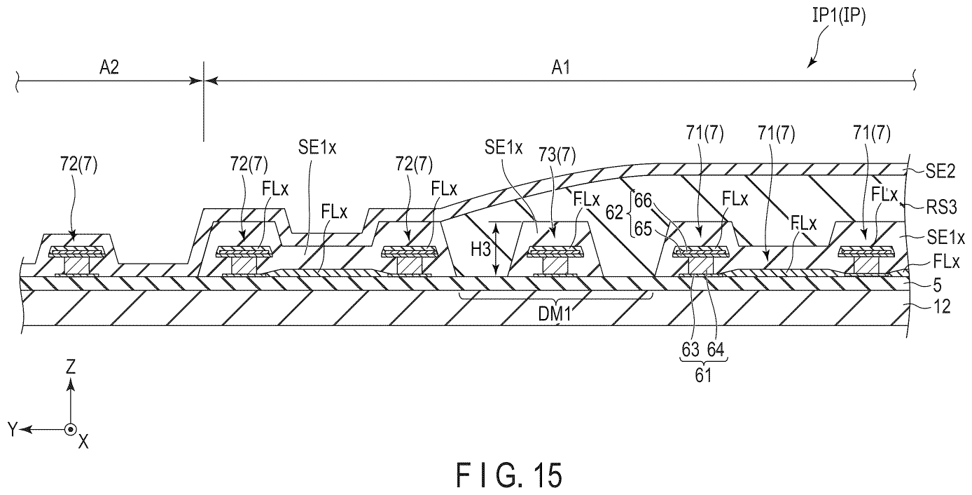

FIG. 15 is a schematic cross-sectional view taken along the line XV-XV in FIG. 14. As described above, the sealing layer SE1x is disposed above the segments 73. From another perspective, at least a part of the sealing layer SE1x is disposed between the respective one of the segments 73 and the resin layer RS3.

With this configuration, it is possible to further enhance the function of the dam DM1 of containing the uncured resin layer RS3. Specifically, when the sealing layer SE1x is disposed above the segment 73, the height H3 becomes higher than the height H2 (shown in FIG. 13). The height H3 corresponds to the distance along the third direction Z from the upper surface of the rib layer 5 to the upper surface of the sealing layer SE1x, which covers the segment 73. The height H2 corresponds to the distance along the third direction Z from the upper surface of the rib layer 5 to the upper surface of the second top layer 66 of the segment 73. By increasing the height H3, it becomes more difficult for the uncured resin layer RS3 to overflow the sealing layer SE1x which covers the segment 73.

With this embodiment, advantageous effects similar to those of the second embodiment can be obtained. In this embodiment, the segment 73 is covered by the sealing layer SE1x. With this configuration, it becomes more difficult for the uncured resin layer RS3 to overflow the sealing layer SE1x covering the segment 73. Therefore, it is easier to form the resin layer RS3 within the desired range compared to the second embodiment.

Note that the example shown in FIG. 15 discloses the case where the dam DM1 is filled with the resin layer RS3, but the dam DM1 may not necessarily be filled with the resin layer RS3.

According to the above-provided embodiments, it is possible to improve the yield of the display device DSP.

The embodiment discloses an example case where the margin area FA includes the area A1 and the area A2, but the margin area FA may further include some other area.

Further, the above-provided embodiments disclose the example cases where the island-shaped portion IP is placed at the four corners within the margin area FA of the panel portion PP, but the arrangement configuration of the island-shaped portions IP is not limited to that of these examples. The island-shaped portions IP may be disposed at locations other than the four corners of the margin area FA, or they may be disposed at both the four corners and the locations other than the four corners.

Furthermore, the above-provided embodiments disclose the example cases where the thickness of the resin layer RS3 is less than the thickness of the resin layer RS1. But the thickness of the resin layer RS3 may as well be equivalent to the thickness of the resin layer RS1.

Moreover, the difference in the planar shape of the segments 71 and 72 as in the above-provided embodiments, or that in the case where the resin layer RS3 is undesirably formed to expand beyond the sealing layer SE1x, can be visually confirmed.

Based on the display devices, the mother boards and the manufacturing methods described above as embodiments of the invention, a person having ordinary skill in the art may achieve display devices, mother boards and manufacturing devices with arbitral design changes; however, as long as they fall within the scope and spirit of the present invention, all of such display devices are encompassed by the scope of the present invention.

A skilled person would conceive various changes and modifications of the present invention within the scope of the technical concept of the invention, and naturally, such changes and modifications are encompassed by the scope of the present invention. For example, if a skilled person adds/deletes/alters a structural element or design to/from/in the above-described embodiments, or adds/deletes/alters a step or a condition to/from/in the above-described embodiment, as long as they fall within the scope and spirit of the present invention, such addition, deletion, and altercation are encompassed by the scope of the present invention.

Furthermore, regarding the present embodiments, any advantage and effect those will be obvious from the description of the specification or arbitrarily conceived by a skilled person are naturally considered achievable by the present invention.

What is claimed is

1. A mother board for a display device, comprising:
a display area for displaying images;
a margin area on an outer side of a cut line for cutting out the display area;
a display element disposed in the display area;
a first partition disposed in the margin area and including a plurality of first segments and a plurality of second segments; and
a first sealing layer formed of an inorganic insulating material, disposed above the display elements and the first segments, and not disposed above the plurality of second segments,
wherein
the plurality of second segments have a planar shape different from that of the plurality of first segments.

2. The mother board of claim 1, wherein
the plurality of first segments have a same planar shape, and
the plurality of second segments have a same planar shape.

3. The mother board of claim 2, wherein
the plurality of first segments each have a first closed area in plan view, and
the plurality of second segments each have a second closed area in plan view, whose planar shape is different from that of the first closed area.

4. The mother board of claim 3, wherein
the plurality of second segments have more second closed areas in plan view, than the first closes areas of the plurality of first segments.

5. The mother board of claim 4, wherein
the plurality of first segments each have one first closed area in plan view, and
the plurality of second segments each have a plurality of second closed areas in plan view.

6. The mother board of claim 3, wherein
an area of the first closed area is larger than an area of the second closed area.

7. The mother board of claim 3, wherein
the plurality of first segments have a first wall portion forming the first closed area,
the plurality of second segments have a second wall portion forming the second closed area, and
an area of the second wall portion is larger than an area of the first wall portion.

8. The mother board of claim 1, wherein
the margin area includes a first area where the plurality of first segments are disposed, and
a second area where the plurality of second segments are disposed.

9. The mother board of claim 8, wherein
the margin area includes a plurality of the first areas, and
the second area surrounds the first areas.

10. A mother board for a display device, comprising:
a display area for displaying images;
a margin area on an outer side of a cut line for cutting out the display area;
an inorganic insulating layer disposed in the display area and the margin area;
a display element disposed in the display area;
a first partition disposed above the inorganic insulating layer in the margin area and including a plurality of first segments and a plurality of second segments;
a first sealing layer formed of an inorganic insulating material, disposed above the display element and the plurality of first segments, and not above the plurality of second segments; and
a resin layer disposed above the first sealing layer in the margin area.

11. The mother board of claim 10, wherein
an end portion of the resin layer is located on the first sealing layer.

12. The mother board of claim 11, wherein
an end portion of the resin layer overlap an end portion of the first sealing layer.

13. The mother board of claim 11, wherein
the resin layer is not disposed above the plurality of second segments.

14. The mother board of claim 11, wherein
the plurality of first segments and the plurality of second segments each include
a first lower portion disposed on the inorganic insulating layer, and
a first upper portion disposed on the first lower portion and protruding from a side surface of the first lower portion.

15. The mother board of claim 14, further comprising:
a second partition disposed in the display area and surrounding the display element,
wherein
the second partition includes
a second lower portion disposed on the inorganic insulating layer, and
a second upper portion disposed on the second lower portion and protruding from the side surfaces of the second lower portion.

16. The mother board of claim 11, further comprising:
a stacked multilayer film including an organic layer and an upper electrode included in the display element, wherein
the stacked multilayer film is disposed between the plurality of first segments and the first sealing layer.

17. The mother board of claim 16, wherein
the stacked multilayer film is disposed in the closed area of each of the plurality of first segments.

18. The mother board of claim 17, wherein
the stacked multilayer film is disposed between each adjacent pair of the plurality of first segments.

19. The mother board of claim 18, wherein
the stacked multilayer film further includes a cap layer disposed on the upper electrode, wherein the cap layer is disposed in the margin area.

20. The mother board of claim 10, further comprising:
a second sealing layer formed of an inorganic insulating material and covering the resin layer and the plurality of second segments.
